(19) United States
(12) Patent Application Publication
(10) Pub. No.: US 2008/0264483 A1
(43) Pub. Date: Oct. 30, 2008

(54) AMORPHOUS SILICON PHOTOVOLTAIC CELLS HAVING IMPROVED LIGHT TRAPPING AND ELECTRICITY-GENERATING METHOD

(76) Inventors: Marvin S. Keshner, Sonora, CA (US); Paul McClelland, Monmouth, OR (US); Rajeewa R. Arya, Beaverton, OR (US)

Correspondence Address: WEISS & MOY PC, 4204 NORTH BROWN AVENUE, SCOTTSDALE, AZ, 85251, US

(21) Appl. No.: 11/875,367

(22) Filed: Oct. 19, 2007

Related U.S. Application Data
(63) Continuation-in-part of application No. 11/740,830, filed on Apr. 26, 2007, now abandoned.

(51) Int. Cl. H01L 31/04

(52) U.S. Cl. 136/256; 136/252

(57) ABSTRACT

An amorphous silicon photovoltaic cell exhibiting improved light trapping, and a method for generating electricity from sunlight therewith. The cell comprises a plurality of layers, including a transparent superstrate; a specular, first transparent conductor positioned below the transparent superstrate; at least one p-i-n structure having an active layer positioned below the first transparent conductor; a second transparent conductor positioned below the p-i-n structure; and a layer of transparent material positioned below the second transparent conductor. The layer of transparent material may be textured amorphous silicon having a relatively high dielectric constant. The cell may further include a back coating positioned below the layer of transparent material, and a back reflector positioned below the back coating layer.

### RELATED APPLICATION

This application is a continuation-in-part of, and claims priority to, U.S. application Ser. No. 11/740,830, filed Apr. 26, 2007, which application is incorporated by reference in its entirety herein for all purposes.

### FIELD OF THE INVENTION

The present invention relates generally to photovoltaic cells containing amorphous silicon. More particularly, the present invention relates to amorphous silicon photovoltaic cells having a p-i-n structure and having light trapping layers to improve absorption of light within the intrinsic layer (i-layer) of the p-i-n structure, and a method for generating electricity from sunlight therewith.

### BACKGROUND OF INVENTION

Photovoltaic solar cells that efficiently convert sunlight into electricity require the sunlight to be mostly absorbed in the photovoltaically active layer that does the conversion from sunlight to electricity. In solar cells made with crystalline silicon, the silicon absorbs weakly at wavelengths longer than 500 nm. Therefore, since most of the sunlight energy is at wavelengths longer than 500 nm, the active layer is typically very thick (150 μm or more) so that it can efficiently absorb most of the light between 500 nm and 1200 nm. However, the cost of this thick layer of silicon is high, and the process for creating a solar cell with a thick layer can be expensive.

Amorphous silicon thin-film photovoltaic solar cells use a thin active layer, often less than 0.5 μm thick. These cells have the advantage that the cost of the material for the active layer can be more than 200 times less than crystalline silicon cells, and the process for creating the active layer can also be less expensive. Amorphous silicon behaves like a direct bandgap semiconductor and absorbs light strongly at wavelengths shorter than 600 nm. However, for an efficient amorphous silicon based solar cell, light must also be strongly absorbed for wavelengths between 600 nm and 750 nm. This is usually accomplished with some form of light trapping that causes the incoming light to bounce back and forth through the active layer multiple times before it escapes back through the surface through which it entered.

A typical prior art amorphous silicon thin-film photovoltaic solar cell consists of several layers (See FIG. 1). In this example, the active layer (16) is the intrinsic (i-layer) of the p-i-n structure, which is hydrogenated, amorphous silicon. The light enters through the top layer (10), which can be glass or another transparent material. Next is a layer of a transparent conductor (12), such as SnO₂. This layer is often textured to scatter light so that the light exits this layer into the p-i-n structure at a slightly different angle from the angle at which it entered. Next to the p-i-n layers (14, 16 and 18) is a set of two layers (20 and 22), typically ZnO and Al, that creates a back reflector and the back conductor. Light enters through the top layer, penetrates into the transparent conductor and is slightly scattered. It then continues through the p-layer, the photovoltaically active I-layer that converts the sunlight to electricity, the n-layer and to the back reflector/conductor, from which the light is reflected back towards the top through the i-layer. Because the angle of the light is slightly scattered in the transparent conductor on each pass, when it finally reaches the top surface, it is often at an angle at which the light is totally internally reflected. In this case, the reflected light returns through the all of the layers, bounces off the back reflector and comes again to the top surface. On average, the light may bounce five times before it is within the range of angles to the top surface that will allow it to escape rather than be reflected again. In effect, the light may go through the active layer 10 times and the active layer absorbs the light as if it were 10 times thicker.

The light trapping approaches used in the prior art have several disadvantages, however. The light only passes through the active layer about 10 times. The efficiency of the solar cell would be greatly improved if the light could be trapped for more bounces. Also, the aluminum layer used as a back reflector has significant absorption for light in the range of 600 nm to 750 nm. Each time the light bounces, about 10% is absorbed by the aluminum. This also limits the number of bounces. Silver can be used for the back reflector and its absorption is much lower. However, silver is expensive and it is easily corroded in outdoor environments. Finally, the amount of texture in SnO₂ transparent conductor can be difficult to control. Too much texture will scatter too much light and prevent light from entering the cell. Too little texture and the number of bounces will be reduced.

### SUMMARY OF THE INVENTION

In accordance with one embodiment of the present invention, a photovoltaic cell is disclosed. The cell comprises, in combination: a transparent superstrate; a first transparent conductor positioned below the transparent superstrate; wherein the first transparent conductor has specular transmission properties and causes no more than minimal scattering of light; at least one p-i-n structure having an active layer positioned below the first transparent conductor; a second transparent conductor positioned below the p-i-n structure(s); and a layer of transparent material positioned below the second transparent conductor.

In accordance with another embodiment of the present invention, a photovoltaic cell is disclosed. The cell comprises, in combination: a transparent superstrate; a first transparent conductor positioned below the transparent superstrate; wherein the first transparent conductor comprises SnO₂; wherein the first transparent conductor has specular transmission properties and causes minimal scattering of the light; at least one p-i-n structure having an active layer positioned below the first transparent conductor; a second transparent conductor positioned below the p-i-n structure(s); a layer of transparent material positioned below the second transparent conductor; wherein the layer of transparent material has a dielectric constant greater than 3; wherein the layer of transparent material is textured; wherein the layer of transparent material is hydrogenated, amorphous silicon; and a back coating positioned below the layer of transparent material.

In accordance with a further embodiment of the present invention, a method for converting sunlight into electricity is disclosed. The method comprises: providing a photovoltaic cell comprising, in combination: a transparent superstrate; a first transparent conductor positioned below the transparent superstrate; wherein the first transparent conductor has specular transmission properties and causes minimal scattering of the light; at least one p-i-n structure having an active layer positioned below the first transparent conductor; a second transparent conductor positioned below the at least one p-i-n structure; and a layer of transparent material positioned below the second transparent conductor; positioning the photovoltaic cell so that sunlight may enter the transparent superstrate and thereafter pass through the active layer of the at least one p-i-n structure, where a portion of the sunlight is converted into electricity; and outputting the electricity from the photovoltaic cell.

### BRIEF DESCRIPTION OF THE DRAWINGS

FIG. 1 is a side, cross-sectional view of a prior art photovoltaic cell.

FIG. 2 is a side, cross-sectional view of a photovoltaic cell consistent with an embodiment of the present invention.

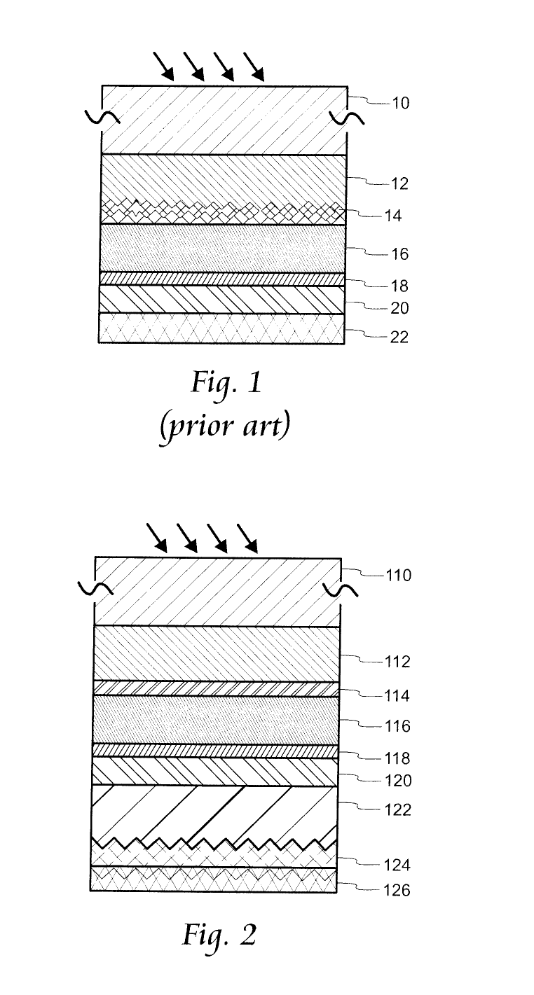

### DETAILED DESCRIPTION OF THE ILLUSTRATED EMBODIMENT

Referring to FIG. 2, an amorphous silicon thin-film photovoltaic cell (hereinafter “cell”) consistent with an embodiment of the present invention is illustrated. The cell comprises multiple layers. These include a transparent superstrate 110, which may be glass or another transparent material. Next in the cell of FIG. 2 is a layer of a transparent conductor 112 such as SnO₂ or ZnO. As noted above, in the prior art, this layer is often textured to scatter approximately 10 to 15% of the incoming light so that the light exits this layer into one or more p-i-n structures at a slightly different angle from the angle at which it entered. In this embodiment, the transparent conductor 112 is not textured, and instead has specular transmission properties with no more than minimal scattering of the incident light. (In this regard, “minimal scattering” means that substantially less than 10% of incoming light is scattered. Preferably, less than one percent of incoming light is scattered and, in one embodiment, scattering may be in the range of approximately 0.1% of incoming light or less.) With the elimination of the texture, the transparent conductor 112 can be optimized to provide better electrical conductivity and better optical transmission than a textured transparent conductor. Thus, it will admit the more light into the active layer (described below) of the cell and absorb or reflect less light. Below the transparent conductor 112 may be located at least one p-i-n structure (comprising layers 114, 116, and 118), of which the active layer that converts sunlight to electricity is the intrinsic (i-layer) 116, which may be hydrogenated, amorphous silicon. (While a single p-i-n structure is shown in FIG. 2, it should be noted that it may be desired to provide more than one p-i-n structure.)

Below the p-i-n structure may be a transparent conductor 120, which may be ZnO or SnZnO. Below the transparent conductor 120 may be a layer of a transparent material 122, with a high dielectric constant (n>3), that may be textured. Below the textured transparent material 122 may be a back coating 124. The back coating 124 may be air, or an organic or inorganic transparent material with a relatively low dielectric constant (e.g. foam, SiO2, etc.). Below the back coating 124 may be provided a back reflector 126, which may comprise aluminum or silver or other desired material.

The transparent conductor 120, if sufficiently thick, may provide the necessary conduction to collect the photo-current from the active layer 116 and conduct the photo-current to the external circuit (not shown). Therefore, the textured transparent layer 122 below the transparent conductor 120 may be either conducting or insulating.

In one embodiment, the textured transparent layer 122 may be hydrogenated, amorphous silicon that is deposited from a hydrogen diluted mixture of silane and hydrogen gases, and at temperatures and pressures so that a relatively very large percentage of hydrogen is incorporated into the Si:H alloy film. (Methods for providing hydrogenated, amorphous silicon having a relatively very large percentage of hydrogen are disclosed in U.S. Pat. No. 7,264,849, issued Sep. 4, 2007, entitled “Roll-Vortex Plasma Chemical Vapor Deposition Method,” the teachings of which are incorporated herein by reference.) With a relatively large percentage of incorporated hydrogen, amorphous silicon (a-Si:H) can be deposited with an optical bandgap approaching Eg=2 eV, and with an index of refraction of n=4.5 at 625 nm. In addition to high levels of hydrogen, some amount of carbon can also be incorporated in amorphous silicon to increase the optical bandgap, maintain a high index of refraction and affect the conductivity of the transparent layer 122. In some embodiments, the combination of process parameters, hydrogen content and carbon content are chosen such that layer 122 is an insulator. In others, hey may be chosen such that layer 122 has a moderate electrical conductivity.

The high bandgap (Eg=2 eV), amorphous silicon with high index of refraction (n=4.5) is used to fabricate the textured transparent layer 122. The high bandgap allows this layer to reflect rather than absorb the wavelengths of light that have already passed through the active layer 116. The high index of refraction and texture makes it a very effective reflector.

Light incident through the transparent superstrate 110 with a wavelength that is shorter than 600 nm may be strongly absorbed in the active layer 116, which may also be a-Si:H, but with a smaller percentage of hydrogen and a lower bandgap (typically Eg=1.7-1.75 eV). The light that is not strongly absorbed by the active layer 116, may pass through the active layer 116, through the transparent conductor 120 and into the textured transparent layer 122. Light in the range from 600 nm-750 nm may be absorbed approximately 50 times less strongly by the relatively high bandgap, textured transparent layer 122, than by the active layer 116. Therefore, almost all of the light that is not absorbed in the active layer 116 passes through the textured transparent layer 122 and to the interface between the textured transparent layer 122 and the back coating 124 at the back of the cell. The light reflects from the interface between layer 122 and the back coating 124, travels back through the active layer, where it has another chance to be absorbed and converted to electricity.

It should be noted that where layers are described herein as textured, a variety of textures may be used. These textures will scatter the light as it passes through the textured layer or reflects from the back surface of the textured layer. As an example, if the texture is random and creates a lambertian surface, then with n=4.5 in the textured material and with air (n=1) as the next layer, 97.5% of the light will experience total internal reflection and be reflected back towards the active layer 116. This value of the reflectance is given by {1−(½n²)}. This approach may be especially effective with a textured material that has a relatively high dielectric constant (n). The light that is not reflected at the interface between the textured transparent layer 122 and the back coating 124 will reach the back reflector 126, where approximately 90% will be reflected back through the cell. Therefore, in total, approximately 99.75% of the light may be reflected back towards the active layer 116.

Once reflected, the light in the range of 600 nm-750 nm will pass through the active layer 116, which will convert some of it to electricity. The majority will again pass through the transparent conductor 112 and the transparent superstrate 110 and to the interface between the transparent superstrate 110 and the ambient air. Here, again assuming that the light has a distribution of angles characteristic of a lambertian reflector, 97.5% of the light will experience total internal reflection. In effect, the light can bounce back and forth through the structure of the cell about 40 times and through the active layer 116 about 80 times. In contrast, with the prior art, the light bounces about 5 times and through the active layers, only about 10 times.

The improved light trapping as compared to the prior art may improve the efficiency of a solar cell in several ways. First, because the transparent conductor 112 is not textured, this improves the amount of light of all wavelengths that enters the solar cell and passes through the p-i-n structure. Second, since the p-layer 114 in a p-i-n device is very thin (approximately 10 nm), the conformal coverage of the transparent conductor 112 by the p-layer 114 is superior for specular (or non-textured) SnO₂ than for textured SnO₂. The better coverage results in lower dark reverse saturation current in the device and enhances the open-circuit voltage (Voc). Third, for the same thickness of active layers as in the prior art, improved light trapping improves the conversion of light in the range of 600-750 nm. Third, with the improved light trapping, the solar cell can be further optimized by thinning the active layer 116. Thinning the active layer 116 reduces the percentage of the photo-current that is lost by carrier trapping and recombination. It improves the percentage of the photocurrent that is collected and also reduces the loss in efficiency from the Stabler-Wronski effect.

A variety of methods can be used to create the texture on the back surface of the textured transparent layer 122. Examples include, but are not limited to:
mechanical texturing by blasting with abrasive particles or rubbing with abrasive brushes
lithographic patterning and then etching
plasma etching with turbulent gas flow
chemical etching (such as used to frost glass)
laser enhanced chemical etching with turbulent gas flow
laser enhanced chemical etching with a laser interference pattern projected onto the surface
deposition methods that encourage the growth of large crystallites
anisotropic chemical etching that enhances the separation of crystallites in the material

In another embodiment, the back reflector 126 may be connected to the second transparent conducting layer 120 to improve the overall conductivity of the back conductor. This can be done by adding a small number of vias between layer 126 and 120. These vias allow the electricity to move from layer 120 to layer 126 which can be a metal such as aluminum, with much better conductivity for electricity than a transparent oxide, such as ZnO. The inclusion of a small number of vias is sufficient to improve the electricity conductivity However, the number of vias is kept small so that the vast majority of the light will reflect from the textured transparent layer 122 rather than from one of the vias.

Although particular embodiments of the invention have been described in detail for purposes of illustration, various modifications may be made without departing from the spirit and scope of the invention. Accordingly, the invention is not to be limited, except as by the appended claims.

We claim:

1. A photovoltaic cell comprising, in combination:
a transparent superstrate;
a first transparent conductor positioned below the transparent superstrate;
wherein the first transparent conductor has specular transmission properties and causes no more than minimal scattering of light;
at least one p-i-n structure having an active layer positioned below the first transparent conductor;
a second transparent conductor positioned below the p-i-n structure; and
a third layer of transparent material positioned below the second transparent conductor.

2. The photovoltaic cell of claim 1 wherein the first transparent conductor comprises one of SnO₂, ZnSnO, ZnO, and a combination of these.

3. The photovoltaic cell of claim 1 wherein the third layer of transparent material has a dielectric constant greater than 3.

4. The photovoltaic cell of claim 3 wherein the third layer of transparent material is textured.

5. The photovoltaic cell of claim 4 wherein the third layer of transparent material is hydrogenated, amorphous silicon.

6. The photovoltaic cell of claim 4 wherein the third layer of transparent material is an amorphous silicon alloy of silicon, carbon, and hydrogen.

7. The photovoltaic cell of claim 4 wherein the third layer of transparent material is an amorphous silicon alloy of silicon, nitrogen, and hydrogen.

8. The photovoltaic cell of claim 1 further comprising a back coating positioned below the third layer of transparent material.

9. The photovoltaic cell of claim 6 wherein the back coating has a relatively low dielectric constant.

10. The photovoltaic cell of claim 7 wherein the back coating comprises one of air, foam, SnO₂, ZnO, ITO and SiO₂.

11. The photovoltaic cell of claim 6 further comprising a reflector positioned below the back coating.

12. The photovoltaic cell of claim 11 wherein the reflector positioned below the back coating is connected through the back coating and the third layer of transparent material with conductive vias.

13. A photovoltaic cell comprising, in combination:
a transparent superstrate;
a first transparent conductor positioned below the transparent superstrate;
wherein the first transparent conductor comprises one of SnO₂, ZnSnO, ZnO, and a combination of these:
wherein the first transparent conductor has specular transmission properties and causes no more than minimal scattering of light;
at least one p-i-n structure having an active layer positioned below the first transparent conductor;
a second transparent conductor positioned below the p-i-n structure;
a third layer of transparent material positioned below the second transparent conductor;
wherein the third layer of transparent material has a dielectric constant greater than 3;
wherein the layer of transparent material is textured;
wherein the third layer of transparent material is hydrogenated, amorphous silicon; and
a back coating positioned below the third layer of transparent material.

14. The photovoltaic cell of claim 13 wherein the back coating has a relatively low dielectric constant.

15. The photovoltaic cell of claim 13 wherein the third layer of transparent material is an amorphous silicon alloy of silicon, carbon, and hydrogen.

16. The photovoltaic cell of claim 13 wherein the third layer of transparent material is an amorphous silicon alloy of silicon, nitrogen, and hydrogen.

17. The photovoltaic cell of claim 13 wherein the back coating comprises one of air, foam, and SiO₂.

18. The photovoltaic cell of claim 13 further comprising a reflector positioned below the back coating.

19. A method for converting sunlight into electricity, comprising:
providing a photovoltaic cell comprising, in combination:
a transparent superstrate;
a first transparent conductor positioned below the transparent superstrate;
wherein the first transparent conductor has specular transmission properties and causes no more than minimal scattering of light;
at least one p-i-n structure having an active layer positioned below the first transparent conductor;
a second transparent conductor positioned below the p-i-n structure; and
a third layer of transparent material positioned below the second transparent conductor.
positioning the photovoltaic cell so that sunlight may enter the transparent superstrate and thereafter pass through the active layer of the p-i-n structure, where a portion of the sunlight is converted into electricity; and
outputting the electricity from the photovoltaic cell.

20. The method of claim 19 wherein the layer of transparent material has a dielectric constant greater than 3 and wherein the layer of transparent material is textured.

21. The method of claim 20 wherein the layer of transparent material is hydrogenated, amorphous silicon.

22. The method of claim 20 further comprising a back coating having a relatively low dielectric constant positioned below the layer of transparent material.

23. The method of claim 22 wherein the back coating comprises one of air, foam, and SiO₂.

24. The method of claim 20 further comprising a reflector positioned below the back coating.

25. The method of claim 20 wherein the hydrogenated, amorphous silicon is deposited from a hydrogen diluted mixture of silane and hydrogen gases at temperatures and pressures so that a relatively very large percentage of hydrogen is incorporated therein.
